(19) United States
(12) Patent Application Publication
(10) Pub. No.: US 2026/0338882 A1
(43) Pub. Date: Oct. 29, 2026

(54) TUNNEL MAGNETORESISTANCE SENSORS AND METHODS

(71) Applicant: GlobalFoundries Singapore Pte. Ltd., Singapore (SG)

(72) Inventors: Abhijit Ghosh, Singapore (SG); Abhishek Talapatra, Dresden (DE); Ganesh Kolliyil Rajan, Singapore (SG); Qingguo Chang, Singapore (SG); Yong Wee Francis Poh, Singapore (SG)

(21) Appl. No.: 19/186,854

(22) Filed: Apr. 23, 2025

(51) Int. Cl. G01R 33/09

(52) U.S. Cl. CPC G01R 33/098

(57) ABSTRACT

A tunnel magnetoresistance (TMR) sensor includes a reference section, a sensing section, and a tunnel barrier layer between the reference and sensing section. The sensing section includes, between the tunnel barrier layer and an antiferromagnetic exchange layer, a stack of alternating ferromagnetic and interlayer exchange coupling layers. Formation of the TMR sensor includes a series of magnetic field and thermal anneal application processes employed to tune the dynamic magnetic field range of the TMR sensor and, particularly, to ensure that the dynamic magnetic field range of the TMR sensor is approximately linear and relatively wide (e.g., ±300 Oe or beyond) due to an exchange coupling chain created by the ferromagnetic and interlayer exchange coupling layer(s) in the stack.

### BACKGROUND

The present disclosure relates to tunnel magnetoresistance (TMR) sensors and, more particularly, to embodiments of a TMR sensor with a relatively wide and approximately linear dynamic range.

A TMR sensor (also referred to herein as a TMR-based field sensor or a TMR field sensor) can include a magnetic tunnel junction (MTJ) for detecting a change in a magnetic field Specifically, a TMR sensor can be subjected to a relatively small magnetic field and, in response to a detected change in that magnetic field, can exhibit a corresponding change in electrical resistance across the MTJ. In other words, a change in the magnetic field across the TMR sensor will result in a change in the voltage drop across the MTJ (provided that the injected current remains constant). Typically, such TMR sensors do not require a wide dynamic range. However, TMR sensors for high current leakage detection applications may require a relatively wide and approximately linear dynamic range. For purposes of this disclosure, a linear dynamic range refers to the linear portion of a detected field exhibited in terms of resistance/voltage (i.e., the difference between the minimum magnetic field strength (Hmin), for example, as measured in Oersteds (Oe) and the maximum magnetic field (Hmax) within which magnetic field-dependent linear changes in resistance are exhibited). Unfortunately, to achieve a relatively wide and approximately linear dynamic range for field sensing, the sensitivity of the TMR sensor (e.g., the change in resistance/the change in applied field) may be compromised.

### SUMMARY

Disclosed herein are embodiments of a tunnel magnetoresistance (TMR) sensor. Generally, embodiments of the TMR sensor can include: a tunnel barrier layer; an electrode; and a sensing section between the tunnel barrier layer and the electrode. The sensing section can include multiple layers. These layers can include at least: a stack of alternating ferromagnetic and interlayer exchange coupling layers; and an antiferromagnetic exchange layer between the stack and the electrode.

Some embodiments of the TMR sensor can include: a first electrode; a second electrode; and a tunnel barrier layer having a first surface and a second surface opposite the first surface. The TMR sensor can further include: a reference section between the first electrode and the first surface of the tunnel barrier layer. The TMR sensor can further include a sensing section between the second surface of the tunnel barrier layer and the second electrode. This sensing section can include multiple layers. These layers can include at least: a stack of alternating ferromagnetic and interlayer exchange coupling layers; and an antiferromagnetic exchange layer between the stack and the second electrode.

Also disclosed herein are embodiments of an associated method of forming a TMR sensor. The method can include forming a tunnel magnetoresistance sensor on a wafer, wherein the tunnel magnetoresistance sensor includes: a first electrode; a second electrode; a tunnel barrier layer having a first surface and a second surface opposite the first surface; a reference section between the first electrode and the first surface of the tunnel barrier layer; and a sensing section between the second surface of the tunnel barrier layer and the second electrode. The sensing section can specifically include multiple layers and these layers can include at least: a stack of alternating ferromagnetic and interlayer exchange coupling layers; and an antiferromagnetic exchange layer between the stack and the second electrode. The method can further include subjecting the wafer to a series of magnetic field and thermal anneal application processes. The series of magnetic field and thermal anneal application processes can be performed, for example, to tune a dynamic magnetic field range of the tunnel magnetoresistance sensor.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1A is a cross-section diagram illustrating an example of a typical TMR sensor;

FIG. 1B is a graph illustrating the dynamic magnetic field range of the TMR sensor of FIG. 1A;

FIGS. 2.1-2.4 are cross-section diagrams illustrating disclosed embodiments of a TMR sensor, respectively;

FIGS. 3A-3B are a process flow diagram and table, respectively, illustrating an example technique in which a series of three magnetic field and thermal anneal processes are performed to achieve a desired dynamic magnetic field range in a disclosed TMR sensor;

FIGS. 4A-4B are a process flow diagram and table, respectively, illustrating one example technique in which a series of four magnetic field and thermal anneal processes are performed to achieve a desired dynamic magnetic field range in a disclosed TMR sensor; and

FIG. 5 is a graph comparing Magnetization (M)-to-Magnetic Field Strength (H) curve 501 for a conventional TMR sensor with no exchange chain in the sensing section to M-to-H curves 502-506 for various examples of a disclosed TMR sensor.

### DETAILED DESCRIPTION

As mentioned above, a TMR sensor refers to a type of sensor capable of detecting a change in an adjacent magnetic field and, more particularly, exhibiting magnetic field-dependent changes in resistance. For example, a current carrying conductor can generate a magnetic field in its vicinity. A TMR sensor adjacent to this area may exhibit a change in resistance in response to a change in the magnetic field generated by the current carrying conductor. Typically, TMR sensors do not require a wide dynamic range. However, TMR sensors that will be used for high current leakage detection applications may require a relatively wide and approximately linear dynamic range. For example, TMR sensors that will be used for detecting leakage current from automotive batteries (which the leakage current magnitudes may have a relatively wide range) require a relatively wide and approximately linear dynamic range.

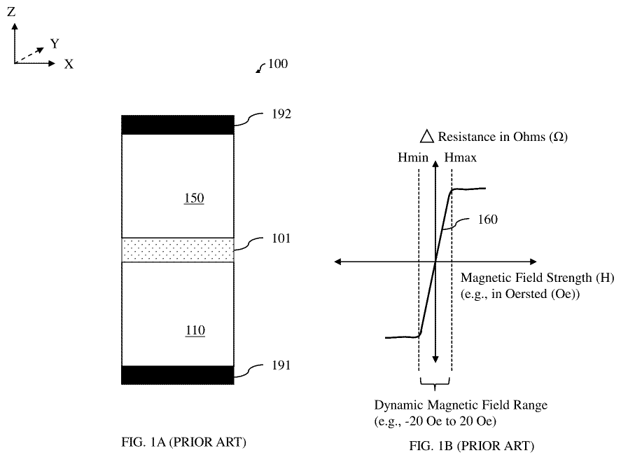

FIG. 1A is a cross-section diagram illustrating a typical TMR sensor 100. FIG. 1B is a graph illustrating the dynamic magnetic field range for the TMR sensor 100 of FIG. 1A. For purposes of this disclosure, the dynamic magnetic field range can refer to the range between Hmin and Hmax (as depicted in FIG. 1B) within which magnetic field-dependent changes in resistance are exhibited by the TMR sensor. As illustrated in FIG. 1B, the TMR sensor 100 is highly sensitive within a relatively narrow dynamic magnetic field range (e.g., between an Hmin of ~−20 Oe and an Hmax of ~+20 Oe).

Specifically, referring to FIG. 1A, TMR sensor 100 can include a reference section 110, a sensing section 150, and a tunnel barrier layer 101 stacked between the reference section 110 and the sensing section 150. TMR sensor 100 can further include a pair of electrodes 191-192: one connected to the reference section 110 opposite tunnel barrier layer 101 and the other connected to the sensing section opposite tunnel barrier layer 101. The reference section 110 and sensing section 150 are each multi-layered structures. The layers of the reference magnetization block are designed to have its net magnetization oriented along X-direction at “zero” applied field condition. The layers of the sensing section 150 are designed to have a second magnetization moment, initially aligned (pinned) along Y, which can rotate in the X-Y plane, in response to the same variable magnetic field applied along the X-direction. When the magnetizations of the reference and sensing sections 110 and 150 are parallel, a low resistance state (Rmin) is obtained (by measuring the voltage across the electrodes 191-192). When the magnetizations of the reference and sensing sections 110 and 150 are antiparallel, a high resistance state (Rmax) is obtained (by measuring the voltage across the electrodes 191-192). Thus, as illustrated by the resistance delta to magnetic field strength curve 160 of FIG. 1B, TMR sensor 100 may exhibit a relatively large increase in resistance in response to a relatively small increase in the magnetic field applied across the X-direction as long as any increase or decrease in that magnetic field falls within the relatively narrow dynamic magnetic field range. However, in some applications (e.g., battery leakage current detection), it may be necessary for a TMR sensor to have a wider dynamic magnetic field range for which the sensitivity might be on the lower side.

In view of the foregoing, disclosed herein are embodiments of a TMR sensor that includes a reference section, a sensing section, and a tunnel barrier layer between the reference and sensing section. In these embodiments, the sensing section is specifically designed to include, between the tunnel barrier layer and a top pinned antiferromagnetic exchange layer, a stack of alternating ferromagnetic and interlayer exchange coupling layers. The stack can include, for example: three layers and, particularly, two ferromagnetic layers separated by an interlayer exchange coupling layer; five layers and, particularly, three ferromagnetic layers with interlayer exchange coupling layers therebetween; seven layers and, particularly, four ferromagnetic layers with interlayer exchange coupling layers therebetween; and so on. The ferromagnetic layers in the stack can all be made of the same ferromagnetic materials or two or more of the ferromagnetic layers in the stack can be made of different ferromagnetic materials. Also disclosed herein are associated method embodiments for forming the TMR sensor. For example, the method can include performing a series of magnetic field and thermal anneal application processes to tune the dynamic magnetic field range of the TMR sensor and, particularly, to ensure that the dynamic magnetic field range of the TMR sensor is approximately linear and relatively wide (e.g., ±300 Oe or beyond) due to an exchange coupling chain created by the ferromagnetic and interlayer exchange coupling layer(s) in the stack.

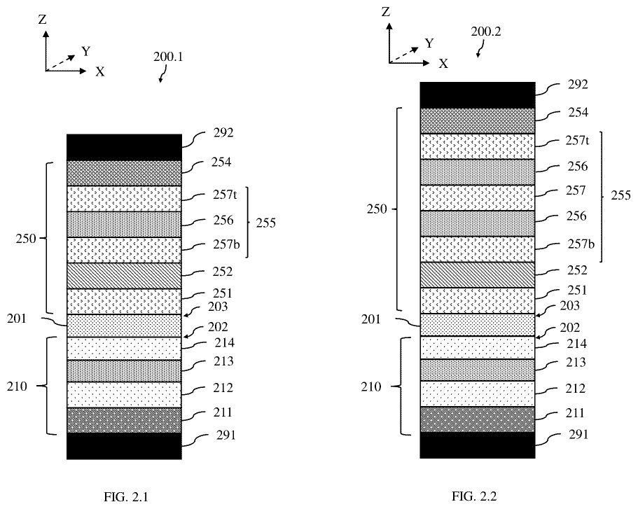

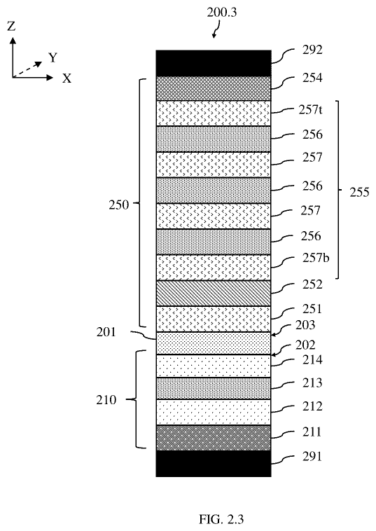

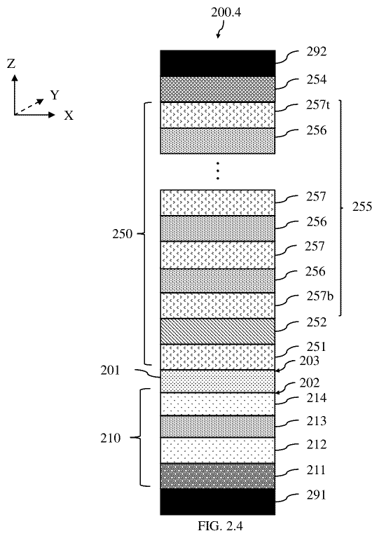

More particularly, FIGS. 2.1-2.4 are cross-section diagrams illustrating disclosed embodiments of a TMR sensor 200.1-200.4, respectively. Referring to FIGS. 2.1-2.4 in combination, TMR sensor 200.1-200.4 can include multiple layers (e.g., stacked vertically, as illustrated). Layers at opposite ends of TMR sensor 200.1-200.4 can be a first electrode 291 and a second electrode 292. First and second electrodes 291-292 can be conductors, each including one or more conductor layers. The conductor layers can include, for example: a ruthenium (Ru) layer, and a tantalum nitride layer (TaN) on the Ru layer. Alternatively, the conductor layers can include an Ru layer, a cooper nitride (CuN) on the Ru layer, and a tantalum layer (Ta) layer on the CuN layer. Alternatively, the conductor layer(s) can include any now known or subsequently developed electrode conductor material or combination of conductor materials. Furthermore, first and second electrodes 291-292 can include the same conductor material(s) or different conductor material(s).

TMR sensor 200.1-200.4 can further include a tunnel barrier layer 201. Tunnel barrier layer 201 can have a first surface 202 (e.g., a bottom surface) and a second surface 203 (e.g., a top surface) opposite the first surface 202. Tunnel barrier layer 201 can be a relatively thin (e.g., a few angstroms to a few nanometers) through which electrons can tunnel. Tunnel barrier layer 201 can be, for example, a magnesium oxide (MgO) layer. Alternatively, tunnel barrier layer 201 could be an aluminum oxide (Al₂O₃) layer (also referred to as alumina) or some other layer suitable for use as a tunnel barrier within a TMR sensor. In some embodiments, tunnel barrier layer 201 can have a thickness of approximately 1.5-2.5 nanometers (nm).

TMR sensor 200.1-200.4 can further include a reference section 210 and a sensing section 250. Reference section 210 (which is a multi-layered structure) can be stacked between and immediately adjacent to first electrode 291 and first surface 202 of tunnel barrier layer 201. Sensing section 250 (which is another multi-layered structure) can be stacked between and immediately adjacent to second surface 203 of tunnel barrier layer 201 and second electrode 292.

More particularly, reference section 210 can include multiple layers. The multiple layers of reference section 210 can include: an antiferromagnetic exchange (AFM) layer 211 immediately adjacent to first electrode 291; a pinned ferromagnetic (FMp) layer 212 on AFM layer 211; an interlayer exchange coupling (EC) layer 213 on FMp layer 212; and a reference ferromagnetic (FMr) layer 214 on EC layer 213. Thus, AFM layer 211 is between and immediately to first electrode 291 and FMp layer 212. EC layer 213 is between and immediately adjacent to FMp layer 212 and FMr layer 214. FMr layer 214 is between and immediately adjacent to EC layer 213 and tunnel barrier layer 201. For purposes of this disclosure, an antiferromagnetic exchange layer refers to a layer of antiferromagnetic material that affects the magnetization of an immediately adjacent ferromagnetic layer.

AFM layer 211 of reference section 210 can include, for example, a layer of platinum manganese (PtMn), a layer of iridium (IrMn), or a layer of any other suitable antiferromagnetic material.

FMp layer 212 of reference section 210 can include, for example, a layer of ferromagnetic material, such as cobalt iron (CoFe) or cobalt iron boron (CoFeB). FMp layer 212 is immediately adjacent to and strongly couples with AFM layer 211 such that it has a magnetization moment with a magnetization vector that is pinned (i.e., fixed or essentially stable) in a first direction, which is parallel to the layers of the TMR sensor and extends laterally across a width of the TMR sensor between opposing sides. Hereinafter the first direction is referred to the X-direction, as illustrated in the figures. Additionally, a second direction, which is also parallel to the layers of the TMR sensor but orthogonal to the X-direction, is referred to herein as the Y-direction.

EC layer 213 of reference section 210 can include, for example, a layer of magnetic material, such as ruthenium (Ru) or iridium (Ir) or tantalum (Ta). This EC layer 213 can couple the immediately adjacent ferromagnetic layers (FMp layer 212 and FMr layer 214) (through indirect exchange coupling and, particularly, the Ruderman-Kittel-Kasuya-Yosida (RKKY) interaction). Thus, EC layer 213 can also be referred to herein as an RKKY layer.

FMr layer 214 can include, for example, another layer of ferromagnetic material, such as CoFe or CoFeB. FMr layer 214 can have a magnetization moment with a magnetization vector that is pinned (i.e., fixed or essentially stable) in the X-direction due to coupling with FMp layer 212 through EC layer 213. Thus, FMp layer 212 effectively controls the magnetization of FMr layer 214. It should be noted that the ferromagnetic materials of FMp layer 212 and FMr layer 214 can be either the same (e.g., both FMp layer 212 and FMr layer 214 could be CoFe or CoFeB) or different (e.g., FMp layer 212 could be CoFe and FMr layer 214 could be CoFeB or vice versa).

Thus, reference section 110 includes a strongly magnetized ferromagnetic layer (i.e., FMp layer 212) coupled to an antiferromagnetic exchanged layer. This strong ferromagnet is coupled to the reference magnetic layer (i.e., FMr layer 214) via one RKKY coupling layer (i.e., EC layer 213).

Sensing section 250 can include multiple layers. The multiple layers of sensing section 250 can include: a free ferromagnetic (FMf) layer 251 immediately adjacent to the second surface 203 of tunnel barrier layer 201; an initial coupling layer 252 on FMf layer 251; a stack 255 of alternating FM layers 257 and EC layers 256 on initial coupling layer 252; and an antiferromagnetic exchange (AFM) layer 254 on stack 255. Thus, FMf layer 251 can be between and immediately adjacent to tunnel barrier layer 201 and initial coupling layer 252. Initial coupling layer 252 can be between and immediately adjacent to FMf layer 251 and a bottom FM layer 257b (i.e., also referred to herein as an initial FM layer) in stack 255. AFM layer 254 can be between and immediately adjacent to a top FM layer 257t (also referred to herein as a last FM layer) in stack 255 and second electrode 292.

FMf layer 251 of sensing section 250 can include, for example, a layer of ferromagnetic material, such as cobalt iron (CoFe) or cobalt iron boron (CoFeB). As mentioned above, FMf layer 251 can be immediately adjacent to tunnel barrier layer 201. Additionally, FMf layer 251 can have a magnetization moment with a magnetization vector that is free (i.e., rotatable) within a plane defined by both the X-direction and the Y-direction (i.e., within the X-Y plane).

Initial coupling layer 252 of sensing section 250 can provide exchange coupling between FMf layer 251 and bottom FM layer 257b. This initial coupling layer 252 can, for example, be a non-magnetic coupling layer, such as a molybdenum (Mo) layer. Such a non-magnetic initial coupling layer 252 could be employed to provide good ferromagnetic coupling between FMf layer 251 and bottom FM layer 257b without structural interference.

As mentioned above, stack 255 of sensing section 250 can include alternating FM layers 257 and EC layers 256.

As illustrated, TMR sensors 200.1 of FIG. 2.1, 200.2 of FIG. 2.2, 200.3 of FIG. 2.3, and 200.4 of FIG. 2.4 vary with regard to the total number of layers in stack 255. For example, referring to FIG. 2.1, stack 255 of sensing section 250 of TMR sensor 200.1 includes a total of three layers including bottom and top FM layers 257b-257t and an EC layer 256 stacked therebetween. Referring to FIG. 2.2, stack 255 of sensing section 250 of TMR sensor 200.2 includes a total of five layers including three FM layers 257 and EC layers 256 therebetween. Referring to FIG. 2.3, stack 255 of sensing section 250 of TMR sensor 200.3 includes a total of seven layers including five FM layers 257 and EC layers 256 therebetween. Referring to FIG. 2.4, alternatively, a sensing section 250 of a TMR sensor 200.4 could include a stack 255 with any odd number n of layers (e.g., where n is greater than three) where the bottom and top FM layers 257b-257t are immediately adjacent to initial coupling layer 252 and AFM layer 254, respectively, and where all FM layers in the stack are separated by EC layers 256.

In any case, each FM layer 257 in stack 255 can include a layer of FM material, such as CoFe or CoFeB. All FM layers 257 in the stack 255 can be made of the same FM material (e.g., all CoFe or all CoFeB). Alternatively, two or more of the FM layers 257 in stack 255 could be made of different FM materials. As discussed in greater detail below with regard to TMR sensor operation, the use of different FM materials for at least some of the FM layers 257 within the stack can be employed to mitigate a hysteresis loop that may develop with the FM materials of the FM layers 257 within stack 255 are all the same. Furthermore, TMR sensors where stack 255 of sensing section 250 has a relatively large total number of layers (e.g., 7 or more, as in TMR sensor 200.3 of FIG. 2.3 or 200.4 of FIG. 2.4) different FM materials in at least some of FM layers 257 may be more robust than TMR sensors where stack 255 has few layers (e.g., 5 or less, as in TMR sensor 200.1 of FIG. 2.1 or 200.2 of FIG. 2.2) and only a single FM material in FM layers 257.

Each EC layer 256 in stack 255 can be made of a magnetic material, such as ruthenium (Ru) or iridium (Ir) or tantalum (Ta), and can provide exchange coupling between the immediately adjacent FM layers 257 above and below (through indirect exchange coupling and, particularly, the RKKY interaction). Thus, these EC layers 256 can also be referred to herein as RKKY layers.

AFM layer 254 of sensing section 250 can include, for example, a layer of platinum manganese (PtMn), a layer of iridium (IrMn), or a layer of any other suitable antiferromagnetic material. The AFM material of AFM layer 254 of sensing section 250 should however be different from the AFM material of AFM layer 251 of reference section 210 so that they are sensitive to different annealing temperatures. Specifically, AFM materials can be selected so that AFM layer 211 of reference section 210 is more sensitive at higher annealing temperatures than AFM layer 254 of sensing section 250. For example, AFM block temperatures for PtMn and IrMn can be 370 °C and 260 °C, respectively. Therefore, in some embodiments, PtMn could be employed for AFM layer 211 of reference section 210 and IrMn could be used for AFM layer 254 of sensing section 250.

Thus, within sensing section 250, stack 255 (in combination with initial coupling layer 252) provides an exchange chain from FMf layer 251 to AFM layer 254 with EC layer(s) coupling (i.e., linking) adjacent layers above and below.

Due to the configurations of reference section 210 and sensing section 250, as described above, and further due to a series of anneal and magnetic field application processes (which are discussed in greater detail below with regard to the method embodiments), reference section 210 can have a first magnetic moment with a first magnetization vector that is pinned (i.e., fixed or essentially stable). The first magnetization vector can specifically be pinned in the X-direction in response to exposure to a variable magnetic field that is applied in the X-direction and that is within a specific, relatively wide, essentially linear, dynamic magnetic field range (e.g., ±300 Oe or beyond). For example, the relatively wide, essentially linear, dynamic magnetic field range of TMR sensor 200.1-200.4 could extend from an Hmin of ~−400 Oe to an Hmax of ~400 Oe, from an Hmin of ~−450 Oe to an Hmax of ~450 Oe, from an Hmin of ~−500 Oe to an Hmax of ~500 Oe, etc. Additionally, sensing section 250 can have second magnetic moment with a second magnetization vector that is, in response to the same variable magnetic field, rotatable in a plane defined by the X and Y directions (i.e., in the X-Y plane).

Various techniques for forming a multi-layered structure on a wafer are known in the art and could be employed to form the multi-layered TMR sensor 200.1-200.4 of FIGS. 2.1-2.4, respectively, as described in detail above. For example, a multi-layered structure for a TMR sensor can be formed on a wafer by: depositing different materials for different layers, in sequence, such that each layer has the desired thickness; and performing a patterning processes (e.g., using lithographic patterning and etch techniques) to ensure that the multi-layered structure has the desired dimensions. Alternatively, a multi-layered structure for a TMR sensor can be formed on a wafer by: patterning a trench in a substrate (e.g., using lithographic patterning and etch techniques; and, for each of the different layers in sequence, depositing a particular material and etching back the material to achieve the desired thickness. Alternatively, any other now known or subsequently developed technique for forming a multi-layered structure on a wafer could be employed. In any case, once a TMR sensor, such as TMR sensor 200.1 of FIG. 2.1, TMR sensor 200.2 of FIG. 2.2, TMR sensor 200.3 of FIG. 2.3 or TMR sensor 200.4 of FIG. 2.4, described in detail above, is formed on a wafer, the wafer can be subjected to a series of magnetic field and thermal anneal application processes. This series of magnetic field and thermal anneal application processes can specifically be performed to tune the dynamic magnetic field range of the TMR sensor 200.1-200.4 and, particularly, to achieve the specific, relatively wide, essentially linear, dynamic magnetic field range, as described above. That is, to achieve a dynamic field range that remains linear within a substantial wider range (e.g., ±300 Oe or beyond) such as, for example, an Hmin of ~−400 Oe to an Hmax of ~400 Oe, from an Hmin of ~−450 Oe to an Hmax of ~450 Oe, from an Hmin of ~−500 Oe to an Hmax of ~500 Oe, etc.

The magnetic field and thermal anneal application processes in the series can include different combinations of processing time, anneal temperature, applied magnetic field strength, and applied magnetic field direction relative to a location of a notch in the wafer. For example, in sequence, the magnetic field and thermal anneal application processes in the series can include progressively decreasing processing times, progressively decreasing anneal temperatures, and progressively decreasing applied magnetic field strengths. In some embodiments, in at least a first process and a last process, the applied magnetic field can be in a first direction and in at least one additional process (which is performed after the first process and before the last process), the applied magnetic field can be in a second direction that is in the same plane as and perpendicular to the first direction. In other embodiments, in a first process the applied magnetic field can be in the first direction, in a second process the applied magnetic field can be in the second direction, and in a third process the applied magnetic field can be switched back to the first direction. In still other embodiments, in a first process the applied magnetic field can be in the first direction, in a second process the applied magnetic field can be in a third direction (which is within the same plane as and between the first direction and the second direction and, thus, not perpendicular to either), a third process where the applied magnetic field is in the second direction, and a fourth process where the applied magnetic field is in the first direction.

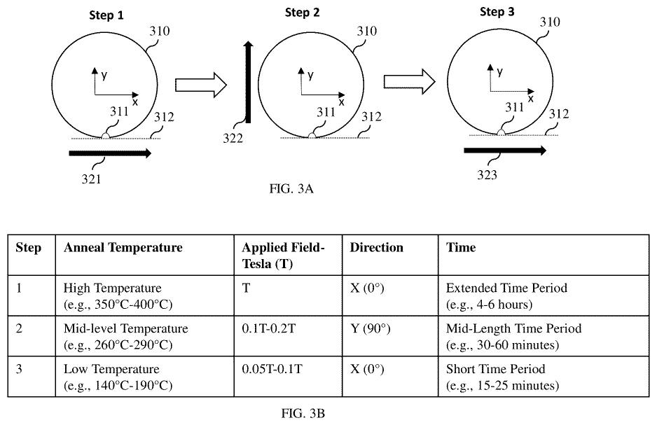

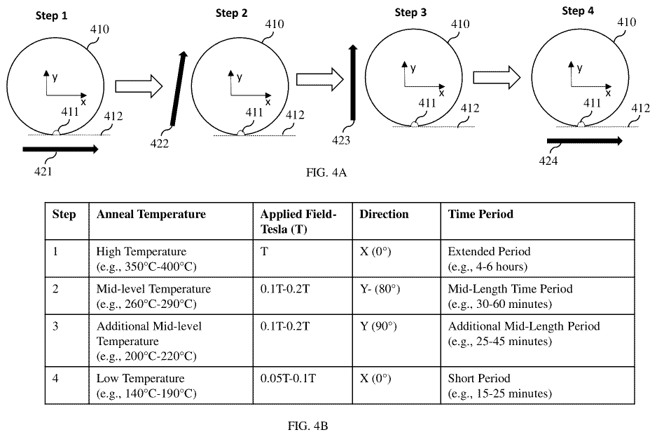

FIGS. 3A-3B illustrate one example technique in which a series of three magnetic field and thermal anneal processes are performed to achieve the desired dynamic magnetic field range. FIGS. 4A-4B illustrate one example technique in which a series of four magnetic field and thermal anneal processes are performed to achieve the desired dynamic magnetic field range.

As illustrated in FIGS. 3A and 4A, each of these techniques can begin with a wafer 310, 410 that includes a TMR sensor (such as any of the TMR sensors 200.1-200.4 disclosed herein). Wafer 310, 410 can include a notch 311, 411 on one side and, particularly, located where a tangent 312, 412 (which is parallel to the X-direction) would touch the wafer. Notch 311, 411 can be employed as a marker during subsequent processing. Each of these techniques can include a series of magnetic field and thermal anneal processes.

Referring specifically to the technique of FIGS. 3A-3B, a first step in the series can include application of a relatively high strength magnetic field (e.g., of 1 Tesla (T)) in the X-direction (see applied field 321) when concurrently being subjected to a relatively high temperature thermal anneal (e.g., at 350 °C-400 °C) for a relatively long (i.e., extended) period of time (e.g., 4-6 hours). A second step in the series can include application of a mid-level strength magnetic field (e.g., of 0.1-0.2 T) in the Y-direction (i.e., orthogonal to the X-direction) (see applied field 322) when concurrently being subjected to a mid-level temperature thermal anneal (e.g., at 260 °C-290 °C) for a mid-length period of time (e.g., 30-60 minutes). The third and last step in the series can include application of a small strength magnetic field (e.g., of 0.05-0.1 T) again in the X-direction (see applied field 323) when concurrently being subjected to a low temperature thermal anneal (e.g., at 140 °C-190 °C) for a relatively short period of time (e.g., 15-25 minutes).

With this technique, step 1 is employed to achieve, within reference section 210, the optimum exchange for AFM layer 211 in order to strongly pin FMp layer 212 and FMr layer 214 in the first direction (i.e., the X-direction). Thus, step 1 ensures that the reference section 210 has a first magnetic moment with a first magnetization vector in the X-direction. Step 2 is employed to achieve, within the sensing section 250, the optimum exchange for AFM layer 254 to bias the sensing section 250 along the Y-direction. As mentioned above, the AFM materials used for the AFM layer 211 of the reference section 210 and for the AFM layer 254 of the sensing section can be selected so that AFM layer 211 of reference section 210 is more sensitive at higher annealing temperatures than AFM layer 254. This difference in AFM materials can ensure that the thermal anneal of step 2 does not (or only minimally) influences the FMp layer 212 and FMr layer 214 of reference section 210. Step 3 is employed for fine alignment adjustments for reference (+Pin) block along the X-direction to mitigate any unwanted remanence field and achieve a symmetric resistance delta to dynamic magnetic field range curve.

Referring specifically to the technique of FIGS. 4A-4B, a first step in the series can include application of a relatively high strength magnetic field (e.g., of 1 Tesla (T)) in the X-direction (see applied field 421) when concurrently subjected to a relatively high temperature thermal anneal (e.g., at 350 °C-400 °C) for a relatively long period of time (e.g., 4-6 hours). A second step in the series can include application of a mid-level strength magnetic field (e.g., of 0.1-0.2 T) in a third direction (which is different from the X and Y directions) (see applied field 422) when concurrently being subjected to a mid-level temperature thermal anneal (e.g., at 260 °C-290 °C) for a mid-length period of time (e.g., 30-60 minutes). The third direction can be in the same plane as the X-Y plane but at less than a 90° angle relative to the X-direction. For example, this third direction can be at a 75°-85° angle (e.g., at an 80° angle) relative to the X-direction. A third step in the series can include application of the same strength magnetic field (e.g., of 0.1-0.2 T) as the second step but in the Y-direction) (see applied field 423) when concurrently being subjected to another mid-level temperature thermal anneal (e.g., at 200 °C-220 °C) (which is less than that used in the second step) for another mid-length period of time (which may be longer or shorter than that used in the second step, e.g., 25-45 minutes). The fourth and last step in the series can include application of a small strength magnetic field (e.g., of 0.05-0.1 T) again in the X-direction (see applied field 424) when concurrently being subjected to a low temperature thermal anneal (e.g., at 140 °C-190 °C) for a relatively short period of time (e.g., 15-25 minutes).

With this technique, step 1 is employed to achieve, within reference section 210, the optimum exchange for AFM layer 211 in order to strongly pin FMp layer 212 and FMr layer 214 in the first direction (i.e., the X-direction). Thus, step 1 ensures that the reference section 210 has a first magnetic moment with a first magnetization vector in the X-direction. Steps 2 and 3 in combination are employed to achieve, within the sensing section 250, the optimum exchange for AFM layer 254 to bias the sensing section 250 along the Y-direction. As mentioned above, the AFM materials used for the AFM layer 211 of the reference section 210 and for the AFM layer 254 of the sensing section can be selected so that AFM layer 211 of reference section 210 is more sensitive at higher annealing temperatures than AFM layer 254. This difference in AFM materials can ensure that the thermal anneal of step 2 does not (or only minimally) influences the FMp layer 212 and FMr layer 214 of reference section 210. Furthermore, by application of magnetic fields in the third direction (e.g., at 80° relative to the X-direction) and in the Y-direction, step 2 assists in mitigating any unwanted coercivity. Step 4 is employed for fine alignment adjustments for reference (+Pin) block along the X-direction to mitigate any unwanted remanence field and achieve a symmetric resistance delta to dynamic magnetic field range curve.

It should be noted that the technique of FIGS. 4A-4B may achieve better fine tuning of the dynamic magnetic field range (e.g., improved linearity and/or a wider range) as compared to the technique of FIGS. 3A-3B. However, there is a trade-off because of added time, complexity, etc. required to complete the series of magnetic field and thermal anneal application processes for the technique of FIGS. 4A-4B as compared to the technique of FIGS. 3A-3B.

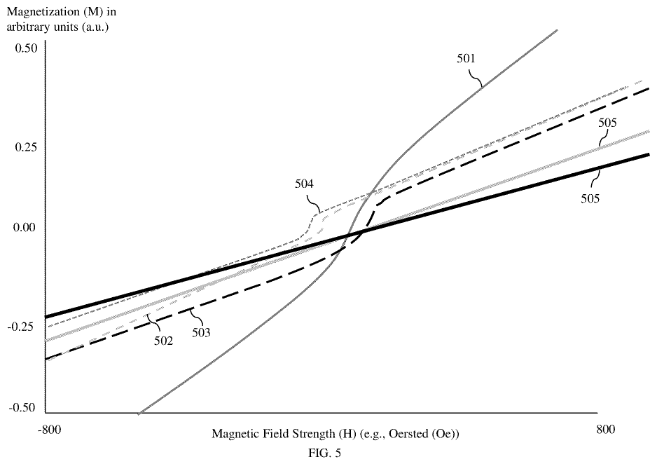

FIG. 5 is a graph comparing Magnetization (M)-to-Magnetic Field Strength (H) curve 501 for a conventional TMR sensor (with no exchange chain in the sensing section) to M-to-H curves 502-506 for various examples of a TMR sensor, as disclosed herein.

M-to-H curve 502 specifically corresponds to TMR sensor 200.1 of FIG. 2.1 with a three-layer stack 255 where all FM layers 257 are made of the same FM material (e.g., all CoFe or all CoFeB), thereby forming an essentially symmetric exchange chain. M-to-H curve 503 specifically corresponds to TMR sensor 200.2 of FIG. 2.2 with a five-layer stack 255 where all FM layers 257 are made of the same FM material (e.g., all CoFe or all CoFeB), thereby forming an essentially symmetric exchange chain with EC links. M-to-H curve 504 specifically corresponds to TMR sensor 200.4 of FIG. 2.4 with a seven-layer stack 255 where all FM layers 257 are made of the same FM material (e.g., all CoFe or all CoFeB), thereby forming an essentially symmetric exchange chain with multiple EC links.

As illustrated, introduction of a three-layer stack of alternating FM and EC layers where all FM layers are made of the same ferromagnetic material results in an increase in linearity of the M-to-H curve 502 as compared to the linearity of M-to-H curve 501. It should, however, be noted that M-to-H curve 502 still shows linearity with two different slopes and a sharp transition from one to the other. Introduction of larger stacks of alternating FM and EC layers provides for even greater improvement in M-to-H curve linearity (e.g., see M-to-H curve 503 achieved with a five-layer stack 255 where all FM layers are made of the same ferromagnetic material, see also M-to-H curve 504 achieved with a seven-layer stack where all FM layers are made of the same ferromagnetic material). It should, however, be noted that, while the overall slope of M-to-H curves 503-504 decreases as compared to M-to-H curves 501 or 502 (reflecting decreased sensitivity), the linearity improves. So, there is a trade-off between achieving an essentially linear, relatively wide, dynamic range and sensitivity.

M-to-H curve 505 specifically corresponds to TMR sensor 200.1 of FIG. 2.1 with a three-layer stack 255 but in this case bottom FM layer 257b and top FM layer 257t are made of different ferromagnetic materials (e.g., one CoFe and CoFeB), thereby forming an asymmetric exchange chain. M-to-H curve 506 specifically corresponds to TMR sensor 200.3 of FIG. 2.3 with a seven-layer stack 255 but in this case the odd FM layers are made of one ferromagnetic material and the even FM layers are made of a different ferromagnetic material, thereby forming an asymmetric exchange chain with multiple EC links. As illustrated by M-to-H curves 505 and 506, introduction of a different ferromagnetic materials into the different FM layers of stack 255 can be employed to mitigate a hysteresis loop present in previously described structures with symmetric exchange chains, further improve linearity, and provide a wider dynamic magnetic field range (e.g., of approximately ±500 Oe).

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A tunnel magnetoresistance sensor comprising:
a tunnel barrier layer;
an electrode; and
a sensing section between the tunnel barrier layer and the electrode, wherein the sensing section includes multiple layers including:
a stack of alternating ferromagnetic and interlayer exchange coupling layers; and
an antiferromagnetic exchange layer between the stack and the electrode.

2. The tunnel magnetoresistance sensor of claim 1, wherein the stack is a three-layer stack including two ferromagnetic layers separated by an interlayer exchange coupling layer and wherein a last ferromagnetic layer in the stack is immediately adjacent to the antiferromagnetic exchange layer.

3. The tunnel magnetoresistance sensor of claim 2, wherein the two ferromagnetic layers in the stack are a same ferromagnetic material.

4. The tunnel magnetoresistance sensor of claim 2, wherein the two ferromagnetic layers in the stack include different ferromagnetic materials.

5. The tunnel magnetoresistance sensor of claim 1, wherein the stack is a five-layer stack including three ferromagnetic layers separated by interlayer exchange coupling layers and wherein a last ferromagnetic layer in the stack is immediately adjacent to the antiferromagnetic exchange layer.

6. The tunnel magnetoresistance sensor of claim 5, wherein the three ferromagnetic layers in the stack are a same ferromagnetic material.

7. The tunnel magnetoresistance sensor of claim 5, wherein at least two of the three ferromagnetic layers in the stack include different ferromagnetic materials.

8. The tunnel magnetoresistance sensor of claim 1, wherein the stack is a seven-layer stack including five ferromagnetic layers separated by interlayer exchange coupling layers and wherein a last ferromagnetic layer in the stack is immediately adjacent to the antiferromagnetic exchange layer.

9. The tunnel magnetoresistance sensor of claim 8, wherein the five ferromagnetic layers in the stack are a same ferromagnetic material.

10. The tunnel magnetoresistance sensor of claim 8, wherein at least two of the five ferromagnetic layers in the stack include different ferromagnetic materials.

11. The tunnel magnetoresistance sensor of claim 1, wherein the stack is a seven-layer stack including five ferromagnetic layers separated by interlayer exchange coupling layers and wherein one of the five ferromagnetic layers is immediately adjacent to the antiferromagnetic exchange layer.

12. The tunnel magnetoresistance sensor of claim 1, wherein the multiple layers of the sensing section further include: a free ferromagnetic layer immediately adjacent to the tunnel barrier layer; and a molybdenum layer stacked between and immediately adjacent to the free ferromagnetic layer and an initial ferromagnetic layer of the stack.

13. A tunnel magnetoresistance sensor comprising:
a first electrode;
a second electrode;
a tunnel barrier layer having a first surface and a second surface opposite the first surface;
a reference section between the first electrode and the first surface of the tunnel barrier layer; and
a sensing section between the second surface of the tunnel barrier layer and the second electrode, wherein the sensing section includes multiple layers including:
a stack of alternating ferromagnetic and interlayer exchange coupling layers; and
an antiferromagnetic exchange layer between the stack and the second electrode.

14. A method comprising:
forming a tunnel magnetoresistance sensor on a wafer, wherein the tunnel magnetoresistance sensor includes:
a first electrode;
a second electrode;
a tunnel barrier layer having a first surface and a second surface opposite the first surface;
a reference section between the first electrode and the first surface of the tunnel barrier layer; and
a sensing section between the second surface of the tunnel barrier layer and the second electrode, wherein the sensing section includes multiple layers including:
a stack of alternating ferromagnetic and interlayer exchange coupling layers; and
an antiferromagnetic exchange layer between the stack and the second electrode; and
subjecting the wafer to a series of magnetic field and thermal anneal application processes, wherein the series of magnetic field and thermal anneal application processes are performed to tune a dynamic magnetic field range of the tunnel magnetoresistance sensor.

15. The method of claim 14, wherein the series of magnetic field and thermal anneal application processes are performed so the dynamic magnetic field range of the tunnel magnetoresistance sensor is approximately linear and further so that:
the reference section has a first magnetic moment with a first magnetization vector that fixed in a first direction when exposed to a variable magnetic field that is applied in the first direction and that is within the dynamic magnetic field range, and
the sensing section has second magnetic moment with a second magnetization vector that is, in response to the variable magnetic field, rotatable in a plane defined by the first direction and a second direction orthogonal to the first direction.

16. The method of claim 15, wherein the series of magnetic field and thermal anneal application processes are performed so the dynamic magnetic field range of the tunnel magnetoresistance sensor is at least ±300 Oersteds.

17. The method of claim 15, wherein the magnetic field and thermal anneal application processes in the series include different combinations of processing time, anneal temperature, applied magnetic field strength, and applied magnetic field direction relative to a location of a notch in the wafer.

18. The method of claim 17,
wherein, in sequence, the magnetic field and thermal anneal application processes in the series include progressively decreasing processing times, progressively decreasing anneal temperatures, and progressively decreasing applied magnetic field strengths, and
wherein in at least a first process and a last process the applied magnetic field direction is the first direction and in an additional process between the first process and the last process the applied magnetic field direction is the second direction.

19. The method of claim 17, wherein the series of magnetic field and thermal anneal application processes include, in sequence, a first process where the applied magnetic field direction is the first direction, a second process where the applied magnetic field direction is the second direction, and a third process where the applied magnetic field direction is the first direction.

20. The method of claim 17, wherein the series of magnetic field and thermal anneal application processes include, in sequence, a first process where the applied magnetic field direction is the first direction, a second process where the applied magnetic field direction is a third direction within the plane and between the first direction and the second direction, a third process where the applied magnetic field direction is the second direction, and a fourth process where the applied magnetic field direction is the first direction.
